(19) United States
(12) Patent Application Publication
(10) Pub. No.: US 2009/0321818 A1
(43) Pub. Date: Dec. 31, 2009

(54) SEMICONDUCTOR COMPONENT WITH TWO-STAGE BODY ZONE

(75) Inventors: Armin Willmeroth, Augsburg (DE); Anton Mauder, Kolbermoor (DE); Winfried Kaindl, Unterhaching (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AUSTRIA AG, Villach (AT)

(21) Appl. No.: 12/164,611

(22) Filed: Jun. 30, 2008

(51) Int. Cl. H01L 29/78; H01L 21/336

(52) U.S. Cl. 257/330; 257/341; 438/289; 257/E29.256; 257/E29.257; 257/E21.417

(57) ABSTRACT

A semiconductor component with a two-stage body zone. One embodiment provides semiconductor component including a drift zone, and a compensation zone of a second conduction type. The compensation zone is arranged in the drift zone. A source zone and a body zone is provided. The body zone is arranged between the source zone and the drift zone. A gate electrode is arranged adjacent to the body zone. The body zone has a first body zone section and a second body zone section, which are adjacent to one another along the gate dielectric and of which the first body zone section is doped more highly than the second body zone section.

### BACKGROUND

Semiconductor components having a drift zone and a compensation zone that is arranged in the drift zone and is doped complementarily to the drift zone—which components are also referred to as compensation components—have a low area-specific on resistance as compared to with components without compensation zones. As a result, for the same absolute on resistance, compensation components can be realized with smaller dimensions, that is to say with a smaller consumption of semiconductor material, than components without a compensation zone.

Owing to its smaller dimensions, a compensation component has smaller parasitic capacitances than a conventional component. When a compensation component is used as a switching element for switching electrical loads, these smaller parasitic capacitances enable faster switching operations and hence steeper switching edges of the electrical signals, that is to say of the electrical voltages present across the switching element and the load and of the electric current flowing through the switching element and the load. If such a compensation component is used for switching an electrical load having a parasitic inductance, then for example steep switching edges of the current flowing through the load during the switching operations can lead to undesirable voltage spikes through the parasitic inductances.

### SUMMARY

One embodiment of the present description relates to a semiconductor component including: a drift zone of a first conduction type; a compensation zone of a second conduction type, which is complementary to the first conduction type, the compensation zone being arranged in the drift zone; a source zone of a first conduction type; a body zone of the second conduction type, the body zone being arranged between the source zone and the drift zone. A gate electrode is arranged adjacent to the body zone. The body zone has a first body zone section and a second body zone section, which are adjacent to one another along the gate dielectric and of which the first body zone section is doped more highly than the second body zone section.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates, on the basis of a cross-sectional illustration, one embodiment of a semiconductor component including a body zone having two body zone sections.

FIG. 2 illustrates one embodiment of an application of the semiconductor component as a switching element for switching a load.

FIG. 3 illustrates the functioning of the semiconductor component during a switch-off operation on the basis of temporal signal profiles.

FIG. 4 illustrates the functioning of the semiconductor component during a switch-on operation on the basis of temporal signal profiles.

FIG. 5 illustrates, on the basis of a cross-sectional illustration, one embodiment of a semiconductor component including a body zone having two body zone sections.

FIG. 6 illustrates, on the basis of a cross-sectional illustration, one embodiment of a semiconductor component including a body zone having two body zone sections.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

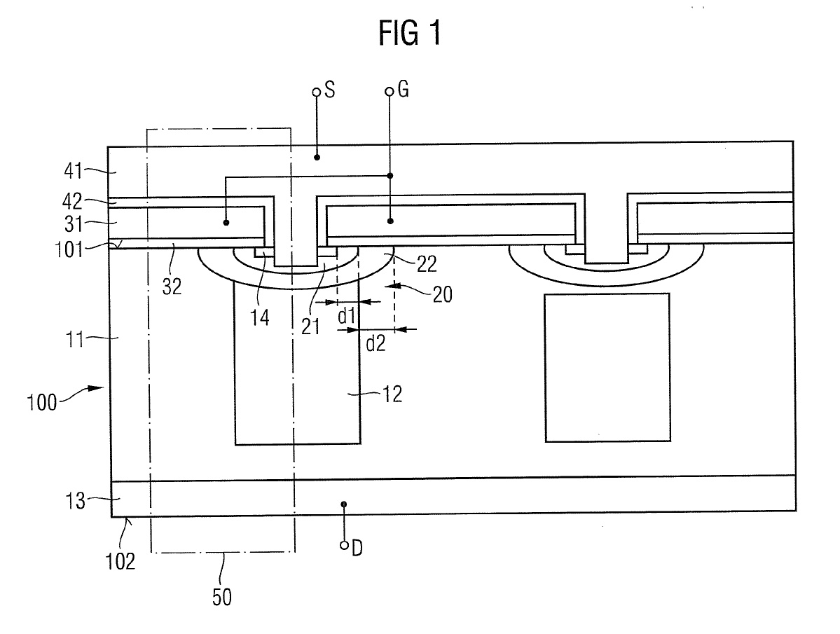

FIG. 1 illustrates one embodiment of a semiconductor component on the basis of a schematic cross-sectional illustration. The semiconductor component illustrated is a MOS transistor component and has a semiconductor body 100 having a first side 101, which is also referred to hereinafter as front side, and having a second side 102, which is also referred to hereinafter as rear side. FIG. 1 illustrates a vertical cross section through the semiconductor body 100, that is to say a cross section in a sectional plane running vertically with respect to the front and rear sides 101, 102 of the semiconductor body.

The MOS transistor component illustrated is realized as compensation component and has in the semiconductor body 100 a drift zone 11 of a first conduction type and at least one compensation zone 12 of a second conduction type, which is complementary to the first conduction type, the at least one compensation zone being arranged in the drift zone 11.

The component additionally has a source zone 14 of the first conduction type and a body zone 20 of the second conduction type, the body zone being arranged between the source zone 14 and the drift zone 11. Contact is made with the source zone 14 by a source electrode 41. The source electrode 41 is composed for example of a metal or a highly doped polycrystalline semiconductor material, such as e.g., polysilicon. In the component illustrated in FIG. 1, the source electrode 41 also makes contact with the body zone 20 apart from the source zone 14, such that the source zone 14 and the body zone 20 are short-circuited, as is known in principle in MOS transistor components.

A gate electrode 31 is present for controlling a conducting channel in the body zone 20 between the source zone 14 and the drift zone 11, the gate electrode being arranged adjacent to the body zone 20 and being dielectrically insulated from the semiconductor body 100 by a gate dielectric 32, such as e.g., a semiconductor oxide. In this case, the gate electrode 31 extends adjacent to the body zone 20 from the source zone 14 as far as the drift zone 11.

A drain zone 13 is adjacent to the drift zone 11 at a side of the drift zone 11 which is remote from the body zone 20. The drain zone 13 is doped more highly than the drift zone 11 and can be of the first conduction type, that is to say of the same conduction type as the drift zone 11, or of the second conduction type. A MOS transistor component formed as a MOSFET is obtained in the case mentioned first, and a MOS transistor component formed as an IGBT is obtained in the other case.

The component illustrated can be realized as an n-conducting component. In this case, the drift zone 11 and the source zone 14 are n-doped, while the body zone 20 and the compensation zone 12 are p-doped. An n-conducting component is turned off if a positive voltage is applied between the drain zone 13 or a drain connection D (which is only illustrated schematically in FIG. 1) and the source zone 14 or a source connection S (which is only illustrated schematically in FIG. 1) and if an electrical potential suitable for forming a conducting channel between the source zone 14 and the drift zone 11 is not present at the gate electrode 31. In a normally off component, in which the source zone 14 and the drift zone 11, on the one hand, and the body zone 20, on the other hand, are doped complementarily to one another, such a conducting channel is an inversion channel. In an n-conducting transistor component, such an inversion channel is formed when an electrical potential that lies above an electrical potential of the source zone 14 at least by the value of a threshold voltage of the component is applied to the gate electrode 31. In this case, the threshold voltage is dependent, in one embodiment, on a doping concentration of the body zone 20 in a region along the gate dielectric 32.

In a p-conducting component, the drift zone 11 and the source zone 14 are p-doped, while the body zone 20 and the compensation zone 12 are n-doped. Such a p-conducting component is turned off when a negative voltage is applied between drain D and source S and if an electrical potential suitable for forming an inversion channel in the body zone 20 is not present at the gate electrode 31. In a p-conducting component, such an inversion channel is formed when an electrical potential that lies below the electrical potential of the source zone 14 by the value of the threshold voltage of the component is applied to the gate electrode 31, wherein the threshold voltage is once again dependent on a doping concentration of the body zone 20 in a region along the gate dielectric 32.

A doping concentration of the drift zone 11 lies for example in the range of 10¹⁵ cm⁻³ to 10¹⁷ cm³, a doping concentration of the compensation zone 12 lies for example in the range of 10¹⁵ cm⁻³ to 10¹⁷ cm⁻³, a doping concentration of the source zone 14 lies for example in the range of 10¹⁹ cm⁻³ to 10²⁰ cm⁻³ and a doping concentration of the drain zone lies for example in the range of 10¹⁹ cm⁻³ for a MOSFET and for example in the range of 10¹⁷ cm⁻³ to 10¹⁹ cm⁻³ for an IGBT.

The component can be realized in cellular fashion and can have a multiplicity of transistor cells of identical type, each having a source zone 14 and a body zone 20. In this case, the individual transistor cells are connected in parallel by the source zones 14 being connected to a common source electrode 41 and by a common gate electrode 31 or a plurality of gate electrode sections that are electrically conductively connected to one another being provided for the individual transistor cells. The drift zone 11 with the compensation zones 12 and also the drain zone 13 are common to all the transistor cells in this case. Such a transistor cell is designated by the reference symbols 50 in FIG. 1. The individual transistor cells can be realized as strip cells. In this case, the source zone 14 and the body zone 20 are formed as elongated semiconductor zones extending in a direction perpendicular to the plane of the drawing illustrated in FIG. 1. The transistor cells can furthermore also be formed as rectangular, in one embodiment square, hexagonal or arbitrarily polygonal transistor cells.

The compensation zone 12 can be adjacent to the body zone 20, as is illustrated by way of example for a transistor cell in the left-hand part of FIG. 1. However, the compensation zone 12 can also be realized in such a way that it is arranged at a distance from the body zone 20, as is illustrated for a transistor cell in the right-hand part of FIG. 1. In a manner not illustrated in more specific detail, in the last-mentioned case it is possible to provide discharge structures at the compensation zone 12, which are used for the purpose that the compensation zone 12, which is charged when the component is turned off, is discharged again upon the transition of the component from the off state to the on state. Such discharge structures are known in principle, such that further explanations in this respect can be dispensed with.

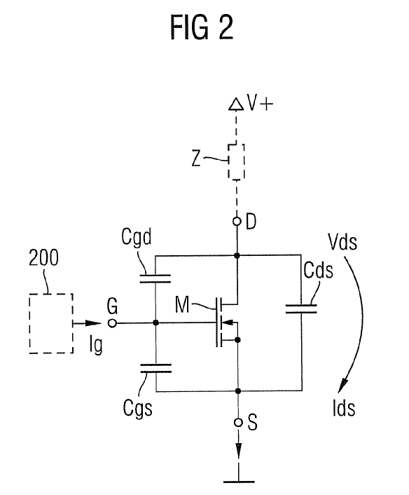

FIG. 2 illustrates one embodiment of an application of such a compensation component as a switching element for switching a load Z. In FIG. 2, M denotes the circuit symbol of the semiconductor component. The circuit symbol illustrated in FIG. 2 represents an n-conducting MOSFET. However, the use of an n-conducting MOSFET in the circuit in accordance with FIG. 2 should be understood merely as an example. Instead of such an n-conducting MOSFET it is also possible to use a p-conducting MOSFET or an IGBT as a switching element. In the exemplary application illustrated in FIG. 2, a load path (drain-source path) of the MOSFET M is connected in series with the load Z between terminals for a positive supply potential V+, on the one hand, and a negative supply potential or reference potential GND, on the other hand. For driving the MOSFET M in the on state or in the off state, a drive circuit 200 (illustrated by dashed lines) is connected to the gate connection G of the MOSFET, the drive circuit being designed to drive the MOSFET M in the on state or in the off state according to a drive signal (not illustrated in more specific detail).

The MOSFET has three parasitic capacitances: a gate-source capacitance Cgs present between the gate connection G and the source connection S; a gate-drain capacitance present between the gate connection G and the drain connection D; and a drain-source capacitance Cds, which is also referred to hereinafter as output capacitance and which is present between the drain connection D and the source connection S. For driving the MOSFET M in the on state, the drive circuit 200 charges the gate-source capacitance Cgs to a voltage lying above a threshold voltage of the MOSFET. For driving the MOSFET M in the off state, the drive circuit 200 discharges the gate-source capacitance Cgs. Ig in FIG. 2 denotes a gate current flowing between the drive circuit 200 and the gate connection G. For driving an n-MOSFET in the on state, the gate current Ig is a positive current, that is to say flows in the direction depicted in FIG. 2. For driving an n-MOSFET in the off state, the current is a negative current, that is to say flows in the opposite current direction to the one depicted in FIG. 2 for the purpose of discharging the gate-source capacitance Cgs.

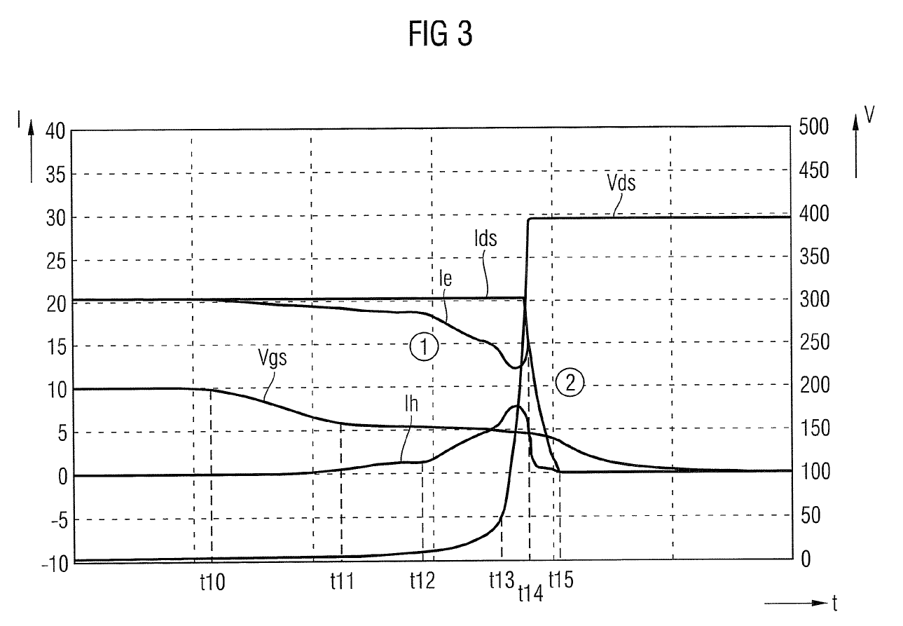

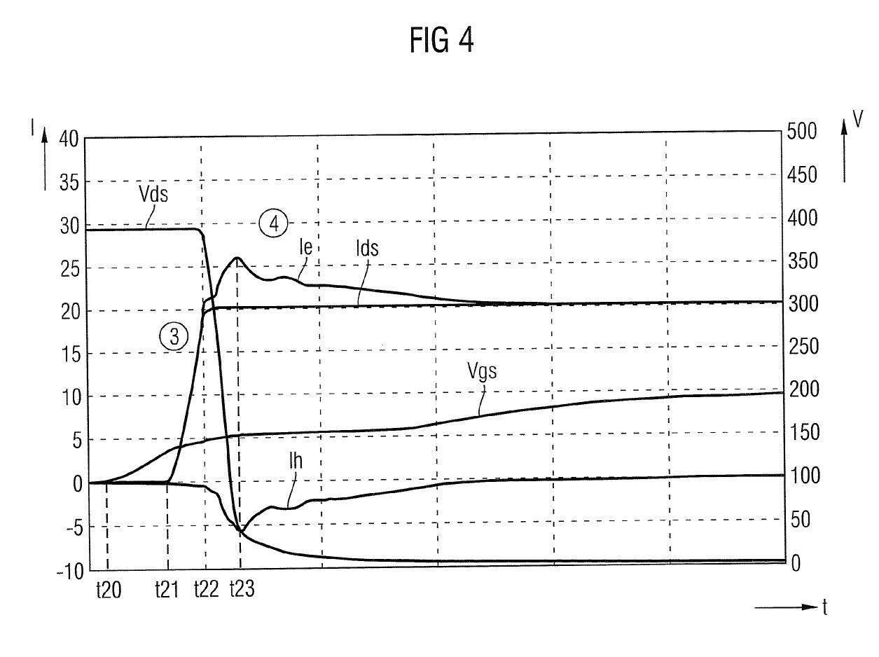

The functioning of the MOS transistor component is explained below with reference to FIG. 3 for a switch-off operation, that is to say for a transition of the component from the on state to the off state, and with reference to FIG. 4 for a switch-on operation, that is to say for a transition of the component from the off state to the on state. For this purpose, FIGS. 3 and 4 illustrate temporal profiles of signals which are relevant to these switching operations. The temporal profiles illustrated in FIGS. 3 and 4 relate to an n-MOSFET, which is turned off if a positive drain-source voltage Vds is applied and if a positive gate-source voltage Vgs sufficient for driving the component in the on state is not present. However, the explanations below can also be applied to a p-channel MOSFET or an IGBT in a corresponding manner.

In FIG. 3, t10 denotes an instant at which a process of driving the MOSFET in the off state begins. Up to this instant, the gate-source capacitance Cgs is charged to an extent such that the gate-source voltage Vgs has a value sufficient for driving the component in the on state. The voltage drop across the load path D-S, that is to say the drain-source voltage Vds, when the component is driven in the on state, is very small in comparison with a supply voltage present between the voltage supply terminals. In the case of an n-MOSFET having a dielectric strength of 600 V, the drain-source voltage Vds when the component is driven in the on state is for example at most only a few volts and can even be less than 1 volt. The process of driving the MOSFET in the off state at the instant t10 begins by the gate-source capacitance Cgs of the MOSFET being discharged by using a discharging current. As a result, the gate-source voltage Vgs firstly falls approximately linearly. Starting from an instant t11—with the same discharging current Ig—the discharge of the gate-source capacitance Cgs and thus the fall in the gate-source voltage Vgs are delayed owing to the Miller effect, which is known in principle. Starting from this instant, apart from the gate-source capacitance Cgs, the gate-drain capacitance Cgd, which is also referred to as the Miller capacitance, is also discharged by using the discharging current Ig. That proportion of the discharging current Ig which discharges the gate-source capacitance Cgs starting from this instant is thereby reduced, whereby a fall in the gate-source voltage Vgs is reduced. The temporal profile of the gate-source voltage Vgs is “flattened” starting from this instant t11. This section of the gate-source voltage Vgs that has a flatter profile is also referred to as the “Miller plateau”.

In FIG. 3, t12 denotes an instant at which the gate-source voltage Vgs has fallen to an extent such that the current-carrying capacity of the inversion channel formed in the body zone 20 under the control of the gate electrode 31 no longer suffices to carry the load current Ids flowing through the MOSFET. In this case, it should be assumed for explanation purposes that the MOSFET M serves for switching an inductive load Z which, when the component is turned off, initially endeavors to maintain the load current Ids flowing until then. Starting from this instant, a space charge zone starts to form in the drift zone 11 proceeding from the pn junction between the body zone 20 and the drift zone 11 and proceeding from the pn junction between the compensation zone 12 and the drift zone 11. Dopant atoms in the compensation zone 12 and the drift zone 11 are ionized owing to the formation of the space charge zone, that is to say that, in the case of a p-doped compensation zone 12, holes flow away from the compensation zone and negatively charged acceptor cores remain in the compensation zone 12, while electrons flow away from the drift zone 11, such that positively charged donor cores remain. In FIG. 3, Ih denotes that proportion of the total load current Ids which is made up of a hole current and Ie denotes that proportion of the total load current Ids which is made up of an electron current. As can be seen on the basis of the time profile, the hole current begins to rise greatly starting from the instant t12 from which the current-carrying capacity of the channel no loner suffices to carry the load current. This is an indication of charge carriers flowing away from the compensation zone 12. The flowing away of the charge carriers from the compensation zone 12 is tantamount to a charging of a junction capacitance which is formed between the compensation zone 12 and the drift zone 11 and which crucially determines the output capacitance Cds of the MOSFET. The instant t12 starting from which the hole current Ih rises thus corresponds to an instant starting from which the output capacitance Cds is charged. The hole current therefore corresponds to a charging current that charges the output capacitance Cds of the MOSFET. The larger the hole current, the more rapidly the output capacitance Cds is charged and the greater a change d(Vds)/dt in the load path voltage or drain-source voltage Vds. In this case, the change in the load path voltage Vds with respect to time crucially determines an electromagnetic interference radiation (EMI, electromagnetic interference) associated with the switch-on operation. As can be gathered from FIG. 3, a rise in the hole current Ih correlates directly with a decrease in the electron current Ie. In this case, the electron current is the current that is still accepted by the channel controlled by the gate electrode 31 in the body zone 20. The more abruptly the conductivity of the channel decreases as the gate-source voltage Vgs falls, then the more steeply the electron current Ie decreases, the more steeply the hole current Ih rises and the steeper the rise in the load path voltage Vds with respect to time, or the greater a change d(Vds)/dt in the load path voltage Vds with respect to time.

In FIG. 3, t14 denotes an instant starting from which the MOSFET M is completely turned off. In an application in accordance with FIG. 2, the load path voltage Vds then corresponds to the supply voltage present between the supply potential terminals.

Switching losses arise during a switching operation. The switching losses correspond to the integral of the electrical energy converted into heat in the component during a switching operation. In this case, the power loss corresponds to the product of load current Ids and load path voltage Vds. In the switch-on operation illustrated with reference to FIG. 3, a large portion of the switching losses is incurred between the instants t13 and t15. In this case, t13 denotes an instant at which the load path voltage Vds has risen to an appreciable value, without the load current Ids having decreased. Such an appreciable value of the load path voltage Vds corresponds for example to between 1% and 10% of the maximum load path voltage, wherein that proportion of the switching losses arising overall which is made up of the switching losses that arise between the instants t13 and t15 is dependent on the total duration of the switching operation.

In FIG. 3, t15 denotes an instant at which the load current Ids has fallen to zero after the component has been completely turned off. The load current still flowing between instants t14 and t15 results from the fact that the gate-source voltage Vgs is still above the threshold voltage at the instant t14. Only at the instant t15 does the gate-source voltage fall to the threshold voltage, as a result of which the load current, or the current through the channel, falls to zero. However, the switching operation has not yet been completely concluded at the instant t15, but rather is not concluded until at a later instant at which the gate-source voltage Vgs has fallen to zero.

In FIG. 4, t20 denotes an instant from which a process of driving the MOSFET in the on state begins and thus starting from which the gate-source capacitance Cgs is charged by using a charging current Ig. In this case, the gate-source voltage Vgs firstly rises approximately linearly until the Miller effect commences at a later instant, the Miller effect bringing about a temporary flattening of a rise in the gate-source voltage Vgs. Starting from an instant t21, the gate-source voltage Vgs has risen to an extent such that a conducting channel is formed in the body zone 20 under the control of the gate electrode 31. The load current Ids rises as a result. In this case, the load path voltage Vds remains at the maximum value that it attained in the course of turn-off in the component until the load current Ids attains its maximum value. The temporal profile in FIG. 4 is based on an application in which the load current Ids is a current which is impressed by a current source or an inductive load and which is accepted by a suitable freewheeling device for example when the MOSFET is turned off.

Upon the transition of the component from the off state to the on state, the junction capacitance formed between the compensation zone 12 and the drift zone 11 or the output capacitance Cds has to be discharged again. The holes that previously flowed away from the compensation zone 12 have to be fed to the compensation zone 12 again, and, in a corresponding manner, the electrons that previously passed out of the drift zone have to be fed to the drift zone again. This means that during the phase of the discharge of the junction capacitance, or the discharge of the output capacitance Cds, an electron current that goes beyond the load current Ids has to flow via the channel formed in the body zone 20. In this case, a change d(Vds)/dt in the output voltage Vds is dependent on how rapidly the junction capacitance is discharged. This depends on how far the electron current Ie can go beyond the load current Ids. In this case, the greater the channel transconductance of the MOSFET, then the greater the extent to which the electron current Ie rises above the load current Ids and the greater the change dVds/dt in the load path voltage Vds with respect to time. In this case, the “channel transconductance” is a measure of a change in a conductivity of the channel, depending on a change in the gate-source voltage Vgs. In this case, the channel transconductance is greater, the greater the extent to which the conductivity of the channel changes for a given change in the gate-source voltage Vgs.

The reverse voltage present also provides for the formation of a space charge zone in the body zone 20. As a result, the channel region is noticeably shortened, which is manifested in an increased transconductance. If the load path voltage Vds then falls, the channel becomes longer and the current decreases despite a constant or even rising gate voltage Vgs. Two different transfer characteristic curves can be specified for the transistor: one for small load path voltages Vds and one for large load path voltages Vds. Starting from the instant t22, the operating point of the component migrates from the characteristic curve for large load path voltages Vds to the characteristic curve for small load path voltages Vds.

In order to optimize the switching behavior of the MOS transistor, the body zone 20, referring to FIG. 1, is realized in two stages in such a way that it has two differently doped body zone sections along the gate dielectric 32: a first body zone section 21, which is adjacent to the source zone 14; and a second body zone section 22, which is arranged between the first body zone section 21 and the drift zone 11. In this case, the first body zone section 21 is doped more highly than the second body zone section 22. A ratio N₂₁/N₂₂ between a doping concentration N₂₁ of the first body zone section 21 and a doping concentration N₂₂ of the second body zone section 22 lies for example between 3 and 10, and in one embodiment between 4 and 6. The two body zone sections 21, 22 are in each case adjacent to the gate dielectric 32 and are arranged adjacent to one another in a current flow direction, that is to say in a direction in which a current flows through the body zone 20 with the channel driven in the on state. The two body zone sections 21, 22 can be realized by semiconductor regions that are doped to different extents: a first, more highly doped semiconductor region, which forms the first body zone section 21 in the region of the gate dielectric 32; and a second, more lightly doped semiconductor region, which forms the second body zone section 22 in the region of the gate dielectric 32. In this case, the first semiconductor region can be surrounded completely by the second semiconductor region within the semiconductor body 100. These two semiconductor regions together form the body zone 20, wherein the compensation zone 12 can be adjacent to the more lightly doped one of the two semiconductor regions. Such semiconductor regions are produced for example by implantation and subsequent indiffusion of dopant atoms.

What are relevant to the switching behavior of the component are the doping concentrations of the first and second drift zone sections 21, 22 in the regions in which they are adjacent to the gate dielectric, and also their dimensions in a current flow direction along the gate dielectric 32. In FIG. 1, these dimensions are designated by d1 for the first drift zone section 21 and by d2 for the second drift zone section 22. In this case, d1 denotes the distance between the source zone 14 and the second drift zone section 22 along the gate dielectric 32, while d2 denotes the distance along the gate dielectric 32 between the first body zone section 21 and the drift zone 11. In this case, the dimensions of the second section 22 along the dielectric can be larger than those of the first section. A ratio d2/d1 of the dimensions lies for example between 0.5 and 5.

The doping concentration of the first body zone section 21 lies for example in the region of 10¹⁷ cm⁻³. The doping concentration of the second body zone section 22 is lower than that of the first body zone section 21 for example by a factor of 3 to 30.

The realization of the body zone 20 with two body zone sections doped to different extents, namely the more highly doped first body zone section 21 adjacent to the source zone 14 and the more lightly doped second body zone section 22 adjacent to the first body zone section 21, results in a channel transconductance of the component that is dependent on the load path voltage or drain-source voltage Vds. At the low drain-source voltages Vds, the channel extends along the gate dielectric 32 over both body zone sections 21, 22. For a channel length d, d=d1+d2 holds true in this case. At higher drain-source voltages Vds, that is to say when a space charge zone has already propagated appreciably proceeding from the pn junction between the body zone 20 and the drift zone 11, the more lightly doped second body zone section 22 is already at least partly depleted, that is to say that the dopant atoms present in the second body zone section 22 are already ionized to an appreciable extent. In this case, the channel length is crucially determined by the dimensions of the first body zone section d1. For the channel length d, the following holds true in this case: d=d1. The channel length crucially determines the channel transconductance of the component. In this case, the channel transconductance is greater, the longer the channel. In the component explained, in which the channel length is reduced at higher drain-source voltages Vds, a higher channel transconductance is present at higher drain source voltages Vds. In this case, the value of the drain-source voltage Vds from which depletion of the second body zone section 22 commences is dependent on the doping concentration of the second body zone section 22. It holds true in this case that the drain-source voltage required to deplete the second body zone section 22 is all the higher, the higher the doping concentration of the second body zone section 22.

The threshold voltage of the component is determined by the (higher) doping concentration of the first body zone section 21. The body zone section 21 is in one embodiment doped so highly that it is never fully depleted even when the component is completely turned off, that is to say at a maximum load path voltage Vds. Otherwise, with the component turned off, the space charge zone would reach as far as the source zone 14, which would lead to a current flow even without a gate-source voltage Vgs present; the component would then no longer be controllable.

Referring to FIG. 3 and the associated explanations, what can be achieved by such voltage-dependent variation of the channel transconductance is that in the range before the instant t13, that is to say at low drain-source voltages Vds, there is a lower channel transconductance and hence a small change d(Vds)/dt in the load path voltage Vds, while a greater channel transconductance and hence a rapid complete switching-off of the component are achieved after the instant t13, that is to say for higher load path voltages Vds, and for a time range in which a large portion of the switching losses arises.

In the switch-on operation illustrated with reference to FIG. 4, the load path voltage Vds is still at its maximum value until the instant t21 (in the range “3”); the channel transconductance is still high up to this instant. This results in a rapid rise in the load current Ids after the instant t21, which leads to low switching losses. The channel transconductance then decreases and has already decreased to its minimum value at an instant t23 at which the maximum channel current flows.

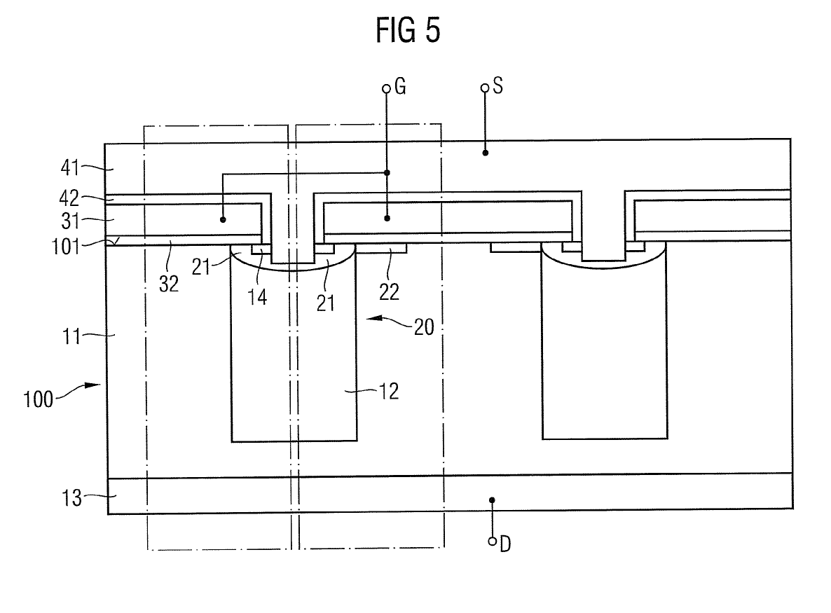

Referring to FIG. 5, in the case of a MOS transistor component realized in cellular fashion, it is possible to provide transistor cells having a body zone 20 formed in two stages, as is illustrated in FIG. 5 for the transistor cell designated by the reference symbol 51. By contrast, other transistor cells can be realized in such a way that they have only one body zone section, as is illustrated in FIG. 5 for the transistor cell designated by the reference symbol 52. In this case, a doping concentration of the body zone 20 of the transistor cell 52 can correspond to a doping concentration of the first body zone section 21 of the transistor cell 51. In this case, the dimensions of the body zone 20 of the transistor cell 52 along the gate dielectric 32 correspond to the dimensions of the first body zone section 21 of the transistor cell 51 along the gate dielectric 32. In the component illustrated in FIG. 5, the second body zone section 22 is a doped semiconductor region arranged directly below the front side 101 along the gate dielectric 32. In contrast to the component in accordance with FIG. 1, the second body zone section 22 in this case is not part of a semiconductor region which surrounds the semiconductor region which forms the first body zone section 21.

The ratio between a number of transistor cells which have a two-stage body zone and the number of transistor cells which have a single-stage body zone can be set as desired and lies for example between 0.1 and 10.

In the embodiment illustrated in FIG. 5, of two transistor cells which have a common body zone 20, one has only one body zone section 21 and the other has two body zone sections 21, 22. In the case of strip cells, in one embodiment, in which the body zones are formed in elongated fashion, transistor cells having only one body zone section 21 and transistor cells having two body zone sections 21, 22 can be arranged alternately in a lateral direction of the semiconductor body; it is also possible for in each case two transistor cells having only one body zone section 21 to follow two transistor cells having two body zone sections 22 (as illustrated). In principle, however, the transistor cells having the different body zones can be distributed as desired taking account of the desired ratio between the number of transistor cells having only one body zone section and the transistor cells having two body zone sections.

The MOS transistor components illustrated in FIGS. 1 and 5 are vertical components. A current flow direction in the drift zone 11 runs in a vertical direction in this component, that is to say in a direction of the semiconductor body 100 that runs perpendicular to the front side 101. It should be pointed out in this connection that the principle explained, namely providing a body zone 20 having two differently doped body zone sections 21, 22, can also be correspondingly applied to lateral components, that is to say to those components in which a current flows in the drift zone in a lateral direction of the semiconductor body and in which the source zone and the drain zone are arranged in the region of the same surface of the semiconductor body.

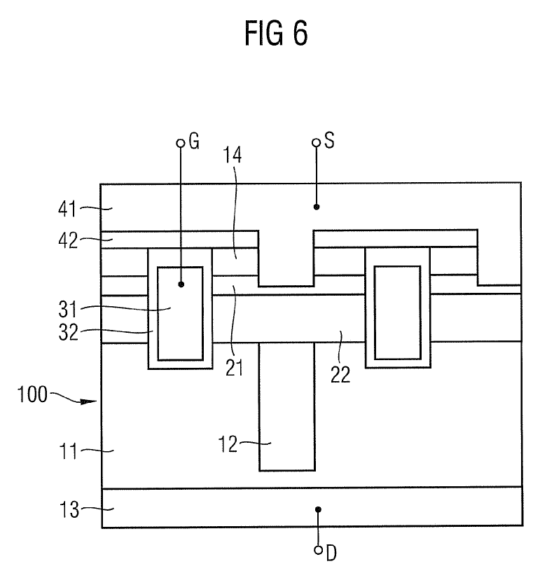

The components illustrated in FIGS. 1 and 5 are additionally planar transistors. In these components, the gate electrode 31 is arranged above the top side 101 of the semiconductor body and realized as a planar electrode. Referring to FIG. 6, a body zone 20 having two differently doped body zone sections 21, 22 can also be provided, of course, in the case of a trench transistor. In the case of such a trench transistor, the gate electrode 31 is arranged in a trench extending into the semiconductor body proceeding from a front side 101. In this case, the gate electrode 31 extends in a vertical direction of the semiconductor body 100 from a source zone 14 right into the drift zone 11 and is arranged adjacent to the drift zone 20 in a manner isolated by the gate dielectric 32. In this case, the more highly doped first body zone section 21 is arranged in a vertical direction between the source zone 14 and the second body zone section 22, while the second body zone section 22 is arranged in a vertical direction of the semiconductor body 21 between the first body zone section 21 and the drift zone 11.

The compensation zone 12 can be adjacent to the body zone 20 (as illustrated), but can also be realized in such a way that it is arranged at a distance from the body zone 20.

The explained transistor component which functions according to the compensation principle can be fully compensated. In this case, the entire dopant charge present in the compensation zones 12 corresponds at least approximately to the dopant charge of the component that is present in the drift zone 11.

Finally, it should be pointed out that component features which have only been explained in connection with one example can be combined with component features from other examples even when this has not been explicitly explained previously. Thus, in particular, features that are represented in one of the following claims can be combined with features of any other claims.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor component comprising:
a drift zone;
a compensation zone, the compensation zone being arranged in the drift zone;
a source zone;
a body zone, the body zone being arranged between the source zone and the drift zone; and
a gate electrode, which is arranged adjacent to the body zone and is dielectrically insulated from the body zone by a gate dielectric;
wherein the body zone has a first body zone section and a second body zone section, which are adjacent to one another along the gate dielectric and of which the first body zone section is doped more highly than the second body zone section.

2. The semiconductor component of claim 1, wherein the first body zone section is adjacent to the source zone.

3. The semiconductor component of claim 1, comprising wherein a ratio between a doping concentration of the first body zone section and a doping concentration of the second body zone section is between 3 and 30.

4. The semiconductor component of claim 1, comprising wherein a ratio between a doping concentration of the first body zone section and a doping concentration of the second body zone section is between 4 and 6.

5. The semiconductor component of claim 1, comprising wherein a first dimension of the first body zone section along the gate electric is smaller than a second dimension of the second body zone section along the gate dielectric.

6. The semiconductor component of claim 1, comprising wherein a ratio between the second dimension and the first dimension is between 0.5 and 5.

7. The semiconductor component of claim 1, comprising wherein the compensation zone is adjacent to the body zone.

8. The semiconductor component of claim 1, comprising:
a drain zone, adjacent to the drift zone at a side remote from the body zone and doped more highly than the drift zone.

9. The semiconductor component of claim 1, realized as a planar component,
wherein the source zone, the body zone, the drift zone and the compensation zone are arranged in a semiconductor body; and
wherein the gate electrode is arranged above a first side of the semiconductor component.

10. A semiconductor component comprising:
a drift zone of a first conduction type;
a compensation zone of a second conduction type, which is complementary to the first conduction type, the compensation zone being arranged in the drift zone;
a source zone of a first conduction type;
a body zone of the second conduction type, the body zone being arranged between the source zone and the drift zone; and
a gate electrode, which is arranged adjacent to the body zone and is dielectrically insulated from the body zone by a gate dielectric;
wherein the body zone has a first body zone section and a second body zone section, which are adjacent to one another along the gate dielectric and of which the first body zone section is doped more highly than the second body zone section.

11. The semiconductor component of claim 10, wherein the first body zone section is adjacent to the source zone.

12. The semiconductor component of claim 10, comprising wherein a ratio between a doping concentration of the first body zone section and a doping concentration of the second body zone section is between 3 and 30.

13. The semiconductor component of claim 10, comprising wherein a ratio between a doping concentration of the first body zone section and a doping concentration of the second body zone section is between 4 and 6.

14. The semiconductor component of claim 10, comprising wherein a first dimension of the first body zone section along the gate electric is smaller than a second dimension of the second body zone section along the gate dielectric.

15. The semiconductor component of claim 10, comprising wherein a ratio between the second dimension and the first dimension is between 0.5 and 5.

16. The semiconductor component of claim 10, comprising wherein the compensation zone is adjacent to the body zone.

17. The semiconductor component of claim 10, comprising:
a drain zone, adjacent to the drift zone at a side remote from the body zone and doped more highly than the drift zone.

18. The semiconductor component of claim 10, realized as a planar component,
wherein the source zone, the body zone, the drift zone and the compensation zone are arranged in a semiconductor body; and
wherein the gate electrode is arranged above a first side of the semiconductor component.

19. The semiconductor component of claim 10, realized as a trench component,
wherein the source zone, the body zone, the drift zone and the compensation zone are arranged in a semiconductor body; and
wherein the gate electrode is arranged in a trench extending into the semiconductor body proceeding from a first side of the semiconductor body.

20. The semiconductor component of claim 10, comprising at least two component cells having in each case a source zone and a body zone, wherein the body zone of a first one of the component cells has a first and a second body zone section and the body zone of a second one of the component cells has only one body zone section.

21. The semiconductor component of claim 20, comprising wherein component cells which have only one body zone section and component cells which have two body zone sections are arranged alternately in a lateral direction of the semiconductor body.

22. The semiconductor component of claim 21, comprising wherein the component cells are strip cells.

23. The semiconductor component of claim 20, comprising wherein a doping concentration of the body zone section of the second component cell corresponds to a doping concentration of the first body zone section of the first component cell.

24. An integrated circuit including a semiconductor component comprising:
a drift zone, a compensation zone, a source zone, a body zone, the body zone and a gate electrode;
wherein the body zone has a first body zone section and a second body zone section, which are adjacent to one another along the gate dielectric and of which the first body zone section is doped more highly than the second body zone section.

25. A method of making a semiconductor component comprising:
forming a drift zone;
forming a compensation zone arranged in the drift zone;
forming a source zone;
forming a body zone between the source zone and the drift zone; and
forming a gate electrode arranged adjacent to the body zone and is dielectrically insulated from the body zone by a gate dielectric;
wherein the body zone has a first body zone section and a second body zone section, which are adjacent to one another along the gate dielectric and of which the first body zone section is doped more highly than the second body zone section.
